(19) United States
(12) Patent Application Publication
(10) Pub. No.: US 2021/0343914 A1
(43) Pub. Date: Nov. 4, 2021

(54) OPTOELECTRONIC SEMICONDUCTOR CHIP HAVING CONTACT ELEMENTS, AND METHOD FOR PRODUCING SAME

(71) Applicant: OSRAM Opto Semiconductors GmbH, Regensbug (DE)

(72) Inventors: Christian LEIRER, Friedberg (DE); Michael SCHUMANN, Neu-Ulm (DE)

(21) Appl. No.: 17/280,193

(22) PCT Filed: Sep. 26, 2019
(86) PCT No.: PCT/EP2019/076065

§ 371 Date: Mar. 26, 2021

(30) Foreign Application Priority Data
Sep. 27, 2018 (DE) 10 2018 123 930.0

(51) Int. Cl. H01L 33/62; H01L 33/22; H01L 33/38; H01L 33/52

(52) U.S. Cl. CPC H01L 33/62; H01L 33/52; H01L 33/385; H01L 33/22

(57) ABSTRACT

An optoelectronic semiconductor chip having first and second semiconductor layers having a first and second conductivity type, respectively, a first and a second current spreading layer, and a first and a second contact element. The first and second semiconductor layers form a layer stack. The first current spreading layer is situated on a side of the first semiconductor layer facing away from the second semiconductor layer and is electrically connected to the first semiconductor layer. The second current spreading layer is situated on the side of the first semiconductor layer facing away from the second semiconductor layer and is electrically connected to the second semiconductor layer. The first and second contact elements are connected to the first and second current spreading layers, respectively. The first or second contact element extends laterally as far as at least one side face of the optoelectronic semiconductor chip.

### CROSS-REFERENCE TO RELATED APPLICATIONS

The present application is a national stage entry according to 35 U.S.C. § 371 of PCT Application No. PCT/EP2019/076065 filed on Sep. 26, 2019; which claims priority to German Patent Application Serial Nos. 10 2018 123 930.0 filed on Sep. 27, 2018; all of which are incorporated herein by reference in their entirety and for all purposes.

### TECHNICAL FIELD

The disclosure relates to optoelectronic devices having optoelectronic semiconductor chips configured to emit electromagnetic radiation.

### BACKGROUND

A light emitting diode (LED) is a light emitting device based on semiconductor materials. For example, an LED includes a pn junction. When electrons and holes recombine with one another in the area of the pn junction, due, for example, to a corresponding voltage being applied, electromagnetic radiation is generated.

In so-called flip-chip components, contact elements for contacting the p and n layers are arranged on a side facing away from the light-emitting surface.

In general, concepts are being sought which allow for optoelectronic semiconductor chips to be further reduced in size.

The object of the present disclosure is to provide an improved optoelectronic semiconductor chip, an improved optoelectronic semiconductor component and an improved method for producing an optoelectronic semiconductor chip.

The object is achieved by the subject matter and the method of the independent patent claims. Advantageous enhancements are defined in the dependent claims.

### SUMMARY

An optoelectronic semiconductor chip comprises a first semiconductor layer of a first conductivity type, a second semiconductor layer of a second conductivity type, first and second current spreading layers and first and second contact elements. The first and second semiconductor layers form a layer stack. The first current spreading layer is arranged on a side of the first semiconductor layer facing away from the second semiconductor layer and is connected to the first semiconductor layer in an electrically conductive manner. The second current spreading layer is arranged on the side of the first semiconductor layer facing away from the second semiconductor layer and is connected to the second semiconductor layer in an electrically conductive manner. The first contact element is connected to the first current spreading layer. The second contact element is connected to the second current spreading layer. The first or second contact element extends laterally to at least one lateral surface of the optoelectronic semiconductor chip.

As an example, the optoelectronic semiconductor chip further includes a potting compound between the first and second contact elements, the potting compound and parts of the first or second contact element forming lateral surfaces of the optoelectronic semiconductor chip.

The first or second contact element may extend laterally to at least two lateral surfaces of the optoelectronic semiconductor chip.

According to embodiments, the second current spreading layer forms a support element of the optoelectronic semiconductor chip.

As an example, the first current spreading layer is arranged adjacent to the first semiconductor layer. Parts of the second current spreading layer are arranged on a side of the first current spreading layer facing away from the first semiconductor layer.

As an example, a lateral surface of the first or second contact element which is different from a lateral surface of the semiconductor chip may extend along at least two directions. In this way, an anchoring structure may be formed.

According to embodiments, an optoelectronic component comprises the optoelectronic semiconductor chip as described above and a lead frame. The optoelectronic semiconductor chip is mounted on the lead frame and the contact elements of the optoelectronic semiconductor chip are electrically connected to contact regions of the lead frame.

According to embodiments, a connecting material for electrically connecting the contact elements to the contact regions of the lead frame may extend along an exposed contact element in a vertical direction of the optoelectronic semiconductor chip.

According to further embodiments, an optoelectronic semiconductor component comprises an array of optoelectronic regions, each of which comprises a first semiconductor layer of a first conductivity type, a second semiconductor layer of a second conductivity type, a first current spreading layer and a first contact element. The first and second semiconductor layers form a layer stack. The first current spreading layer is arranged on a side of the first semiconductor layer facing away from the second semiconductor layer and is connected to the first semiconductor layer in an electrically conductive manner. The first contact element is connected to the first current spreading layer. The optoelectronic semiconductor component further comprises a second current spreading layer and a second contact element. The second current spreading layer is arranged on the side of the first semiconductor layer facing away from the second semiconductor layer and is respectively connected to the second semiconductor layer of the optoelectronic regions. The second contact element is connected to the second current spreading layer.

According to embodiments, the optoelectronic semiconductor component comprises a plurality of second contact elements.

As an example, the second contact elements are arranged in an edge region of the optoelectronic semiconductor component.

According to embodiments, the second contact elements surround the first contact elements in an annular manner. As an example, the second contact elements extend to a lateral surface of the optoelectronic semiconductor component.

A method for producing an optoelectronic semiconductor chip comprises forming a layer stack comprising a first semiconductor layer of a first conductivity type and a second semiconductor layer of a second conductivity type, forming first and second current spreading layers, and forming first and second contact elements. The first current spreading layer is formed on a side of the first semiconductor layer facing away from the second semiconductor layer and is connected to the first semiconductor layer in an electrically conductive manner. The second current spreading layer is formed on the side of the first semiconductor layer facing away from the second semiconductor layer and is connected to the second semiconductor layer in an electrically conductive manner. The first contact element is connected to the first current spreading layer. The second contact element is connected to the second current spreading layer. The first or second contact element extends laterally to at least one lateral surface of the optoelectronic semiconductor chip.

As an example, the method includes processing a wafer which includes a plurality of semiconductor chips, wherein the first or second contact elements of adjacent semiconductor chips are each arranged adjacent to one another. Forming the first contact elements comprises forming a conductive structure which is associated with a plurality of adjacent semiconductor chips. The method may further comprise singulating the wafer into semiconductor chips, wherein the conductive structure is divided among the associated semiconductor chips. Furthermore, forming the second contact elements may comprise forming a conductive structure which is associated with a plurality of adjacent semiconductor chips.

According to embodiments, an optoelectronic device comprises the optoelectronic semiconductor component or the optoelectronic semiconductor chip or the optoelectronic component as described above. As an example, the optoelectronic device additionally comprises a driver circuit by means of which the first contact elements of the optoelectronic regions may be controlled.

### BRIEF DESCRIPTION OF THE DRAWINGS

The accompanying drawings serve to provide an understanding of non-limiting embodiments. The drawings illustrate non-limiting embodiments and, together with the description, serve for explanation thereof. Further non-limiting embodiments and many of the intended advantages will become apparent directly from the following detailed description. The elements and structures shown in the drawings are not necessarily shown to scale relative to each other. Like reference numerals refer to like or corresponding elements and structures.

FIG. 1A shows a vertical cross-sectional view through two adjacent optoelectronic semiconductor chips according to embodiments.

FIGS. 1B and 1C show a schematic top view of a second main surface of a semiconductor chip according to embodiments.

FIG. 2A shows a vertical cross-sectional view through two adjacent semiconductor chips according to embodiments.

FIGS. 2B, 2C and 2D each show schematic top views of a second main surface of a semiconductor chip according to embodiments.

FIG. 3A shows a vertical cross-sectional view of an optoelectronic component according to embodiments.

FIGS. 3B and 3C each show a schematic side view of an optoelectronic semiconductor chip according to embodiments.

FIG. 4 shows a schematic view of an array of semiconductor chips.

FIG. 5A shows a vertical cross-sectional view through part of an optoelectronic semiconductor component.

FIGS. 5B, 5C and 5D each show a schematic top view of a second main surface of an optoelectronic semiconductor component according to embodiments.

FIG. 6A shows a vertical cross-sectional view of a workpiece during production of optoelectronic semiconductor chips.

FIGS. 6B to 6F each show schematic top views of a second main surface of a workpiece during production of optoelectronic semiconductor chips.

FIGS. 6G to 6I each show schematic top views of a second main surface of an optoelectronic semiconductor chip according to embodiments.

FIG. 7 shows a schematic view of an optoelectronic device according to embodiments.

FIG. 8 outlines a method according to embodiments.

### DETAILED DESCRIPTION

In the following detailed description, reference is made to the accompanying drawings, which form a part of the disclosure and in which specific exemplary embodiments are shown for purposes of illustration. In this context, directional terminology such as “top”, “bottom”, “front”, “back”, “over”, “on”, “in front”, “behind”, “leading”, “trailing”, etc. refers to the orientation of the figures just described. As the components of the exemplary embodiments may be positioned in different orientations, the directional terminology is used by way of explanation only and is in no way intended to be limiting.

The description of the exemplary embodiments is not limiting, since there are also other exemplary embodiments, and structural or logical changes may be made without departing from the scope as defined by the patent claims. In particular, elements of the exemplary embodiments described below may be combined with elements from others of the exemplary embodiments described, unless the context indicates otherwise.

The terms “wafer” or “semiconductor substrate” used in the following description may include any semiconductor-based structure that has a semiconductor surface. Wafer and structure are to be understood to include doped and undoped semiconductors, epitaxial semiconductor layers, supported by a base, if applicable, and further semiconductor structures. For example, a layer of a first semiconductor material may be grown on a growth substrate made of a second semiconductor material or of an insulating material, for example sapphire. Depending on the intended use, the semiconductor may be based on a direct or an indirect semiconductor material. Examples of semiconductor materials particularly suitable for generating electromagnetic radiation include, without limitation, nitride semiconductor compounds, by means of which, for example, ultraviolet, blue or longer-wave light may be generated, such as GaN, InGaN, AlN, AlGaN, AlGaInN, phosphide semiconductor compounds by means of which, for example, green or longer-wave light may be generated, such as GaAsP, AlGaInP, GaP, AlGaP, and other semiconductor materials such as AlGaAs, SiC, ZnSe, GaAs, ZnO, Ga₂O₃, diamond, hexagonal BN and combinations of the materials mentioned. The stoichiometric ratio of the ternary compounds may vary. Other examples of semiconductor materials may include silicon, silicon germanium, and germanium. In the context of the present description, the term “semiconductor” also includes organic semiconductor materials.

The term “substrate” generally includes insulating, conductive or semiconductor substrates.

The terms “lateral” and “horizontal”, as used in the present description, are intended to describe an orientation or alignment which extends essentially parallel to a first surface of a semiconductor substrate or semiconductor body. This may be the surface of a wafer or a chip (die), for example.

The horizontal direction may for example be in a plane perpendicular to a direction of growth when layers are grown.

The term “vertical” as used in this description is intended to describe an orientation which is essentially perpendicular to the first surface of the semiconductor substrate or semiconductor body. The vertical direction may correspond, for example, to a direction of growth when layers are grown.

To the extent used herein, the terms “have”, “include”, “comprise”, and the like are open-ended terms that indicate the presence of said elements or features, but do not exclude the presence of further elements or features. The indefinite articles and the definite articles include both the plural and the singular, unless the context clearly indicates otherwise.

In the context of this description, the term “electrically connected” means a low-ohmic electrical connection between the connected elements. The electrically connected elements need not necessarily be directly connected to one another. Further elements may be arranged between electrically connected elements.

The term “electrically connected” also encompasses tunnel contacts between the connected elements.

Each of the optoelectronic semiconductor chips or components or semiconductor components described in the context of the present description may both emit electromagnetic radiation and receive electromagnetic radiation. Although emission of electromagnetic radiation is particularly described in some passages, it goes without saying that the elements described may be applied to light-receiving components in an analogous manner.

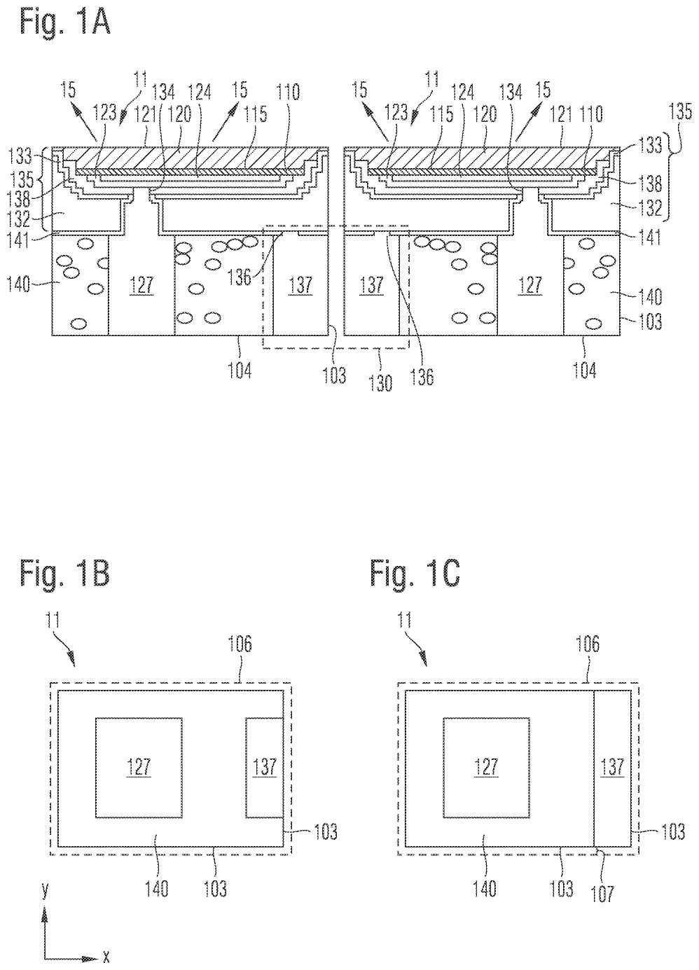

FIG. 1A shows a cross-sectional view of two optoelectronic semiconductor chips 11. The optoelectronic semiconductor chips 11 each include a first semiconductor layer 110 of a first conductivity type, for example p-type, and a second semiconductor layer 120 of a second conductivity type, for example n-type. The optoelectronic semiconductor chips 11 furthermore comprise a first current spreading layer 123 and a second current spreading layer 132 as well as a first contact element 127 and a second contact element 137. The first and second semiconductor layer 110, 120 form a layer stack. That is, the first and second semiconductor layers 110, 120 are stacked on top of each other. In this case, electromagnetic radiation 15 emitted or received by the optoelectronic semiconductor chip is output or received via a first main surface 121 of the second semiconductor layer 120. The first current spreading layer 123 is arranged on a side of the first semiconductor layer 110 facing away from the second semiconductor layer 120 and is connected to the first semiconductor layer 110 in an electrically conductive manner. The second current spreading layer 132 is also arranged on the side of the first semiconductor layer 110 facing away from the second semiconductor layer and is connected to the second semiconductor layer in an electrically conductive manner. According to all of the embodiments described herein, the layer thickness of the second current spreading layer 132 may be smaller than or approximately as great as the layer thickness of the second semiconductor layer 120. The term “layer thickness” relates to a layer thickness as measured in a region where the second current spreading layer 132 overlaps with the first current spreading layer 123. The layer thickness of the first and second contact elements 127, 137 may each be greater than the layer thickness of the second semiconductor layer 120.

The first contact element 127 is connected to the first current spreading layer 123 in an electrically conductive manner. The second contact element 137 is connected to the second current spreading layer 132 in an electrically conductive manner. The second contact element extends laterally to at least one lateral surface 103 of the optoelectronic semiconductor chip 11. The lateral surface 103 of the optoelectronic semiconductor chip 11 is determined by the dividing line along which a workpiece, for example a wafer, is singulated during the production process in order to produce the individual semiconductor chips 11. This will be discussed in more detail later. According to embodiments, the lateral surface 103 therefore does not necessarily coincide with a lateral delimitation of the first and second semiconductor layers 110, 120. Rather, as illustrated, for example, in FIG. 1A, further layers are formed on the lateral surfaces of the first and second semiconductor layers 110, 120 and one lateral surface of these layers ultimately forms the lateral surface 103 of the optoelectronic semiconductor chip. For example, the first main surface 121 of the second semiconductor layer 120, via which emission of the electromagnetic radiation may take place, may be roughened.

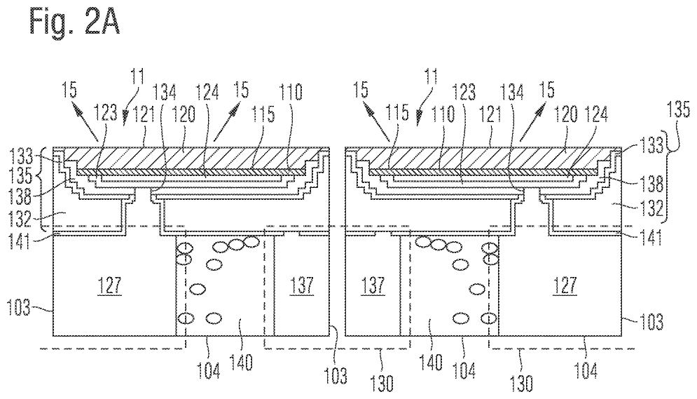

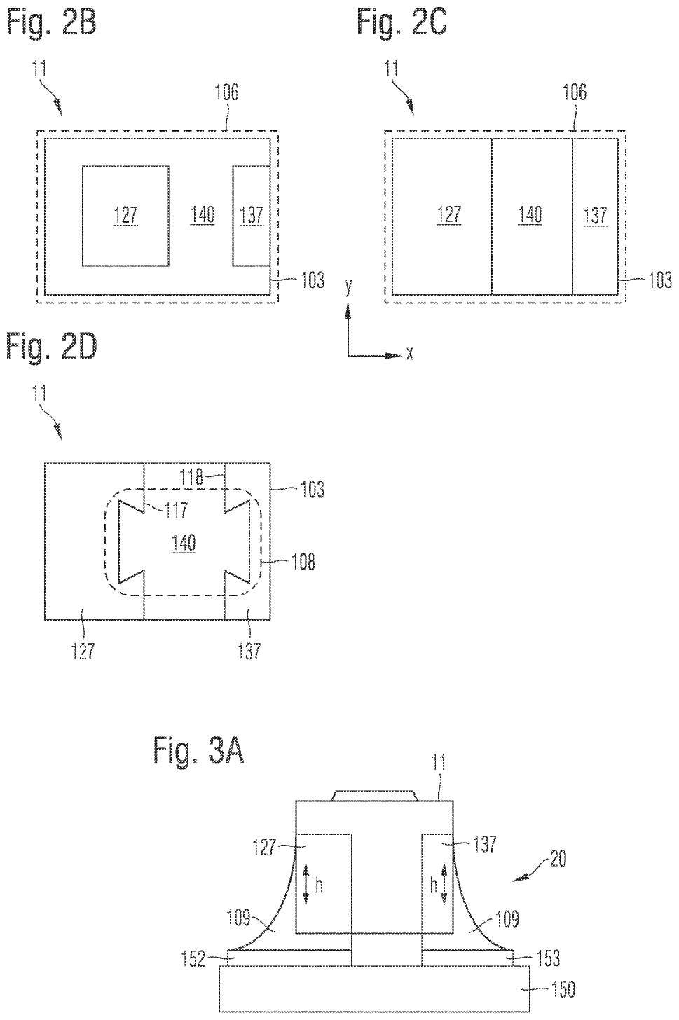

According to further embodiments, as described below with reference to FIG. 2A, the first contact element 127 may alternatively or additionally extend laterally to at least one lateral surface 103 of the optoelectronic semiconductor chip 11. An active zone 115 may be arranged between the first semiconductor layer 110 and the second semiconductor layer 120. The active zone 115 may, for example, comprise a pn junction, a double heterostructure, a single quantum well structure (SQW, single quantum well) or a multiple quantum well structure (MQW, multi quantum well) for generating radiation. The term “quantum well structure” does not imply any particular meaning here with regard to the dimensionality of the quantization. Therefore it includes, among other things, quantum wells, quantum wires and quantum dots as well as any combination of these layers.

According to embodiments, the first and second semiconductor layers 110, 120 may each include GaN, for example a GaN-containing compound semiconductor material.

A first current spreading layer 123 may be arranged directly adjacent to the first semiconductor layer 110. In the context of the present description, the term “first current spreading layer” or “second current spreading layer” denotes any layer or layer structure that is connected to the first or second semiconductor layer and is formed in a planar manner. The first current spreading layer does not necessarily need to be arranged in direct contact with the first semiconductor layer 110. In a corresponding manner, the second current spreading layer 132 does not necessarily need to be arranged in direct contact with the second semiconductor layer 120.

As an example, a metallic mirror layer 124 may be formed adjacent to the first semiconductor layer 110. The metallic mirror layer 124 may, for example, comprise or be composed of silver. A portion of the first current spreading layer 123 may completely enclose the metallic mirror layer 124. That is, a portion of the first current spreading layer 123 may be formed on the exposed upper and lateral surfaces of the metallic mirror layer 124, thereby effecting encapsulation of the metallic mirror layer 124. Further portions of the first current spreading layer may be directly adjacent to the first semiconductor layer 110. Examples of materials of the first current spreading layer 123 include, among others, nickel, aluminum, silver, chromium, titanium, tungsten or conductive nitride compounds.

An insulating layer 138 is arranged over the first current spreading layer 123 and the other conductive layers. As an example, the insulation layer 138 may include silicon oxide, silicon nitride, a combination of these materials, and others. According to embodiments, the first current spreading layer 123 is arranged between the first semiconductor layer 110 and the second current spreading layer 132. The second current spreading layer 132 may, for example, include nickel, aluminum, silver, chromium, titanium, tungsten and/or conductive nitride compounds or may be composed of aluminum and constitute a support element 135 for the optoelectronic semiconductor chip 11. As an example, a contact layer 133 may be arranged between the conductive layer 132 and the adjacent insulating material 138 or the second semiconductor layer 120.

An opening 134 may be formed in the insulation layer 138 and the second current spreading layer 132. A layer of insulating material 141 may cover sidewalls of the opening 134. The first contact element 127 may be connected to a conductive structure in the opening 134 via a conductive material. For example, the first current spreading layer 123 may in this manner be connected to the first contact element 127. The first contact element 127 is electrically insulated from the second current spreading layer 132 by the insulation material 141.

As an example, the second current spreading layer 132 may be directly connected to the second semiconductor layer 120 in the edge region of the semiconductor chip 11. According to further concepts, however, it is also possible for further openings to be arranged in the first semiconductor layer 110 as well as the first current spreading layer 123 and the adjacent conductive layers in order to connect the second semiconductor layer 120 to the second current spreading layer 132. The second contact element 137 may be connected to the second current spreading layer via an opening 136 in the insulation material 141. A filler material or a potting compound 140 may be arranged, for example, between the first and the second contact elements 127, 137 for mechanical stabilization. The potting compound 140 may, for example, extend to the edge of the chip, thus forming a side wall or lateral surface 103 of the optoelectronic semiconductor chip 11.

According to the embodiments illustrated in FIG. 1A, the second contact elements 137 each extend to a lateral surface 103 of the optoelectronic semiconductor chip 11. In this case, the lateral surface 103 of the optoelectronic semiconductor chip is not formed in this area by the potting compound 140, but rather by each of the second contact elements 137. As further indicated in FIG. 1A, the second contact element 137 may in each case be produced by severing a conductive structure 130.

FIG. 1B shows a top view of a second main surface 104 of the optoelectronic semiconductor chip 11 according to embodiments. FIG. 1B illustrates, by a dashed line 106, a dividing line where the individual chips are sawed apart or diced. The dividing line 106 is located within the sawing frame or kerf 107. As may be seen, the second contact element 137 is arranged adjacent to a lateral surface 103 of the optoelectronic semiconductor chip 11. The first contact element 127 is arranged in a central region. That is, potting compound 140 is arranged between each of the boundaries of the first contact element 127 and the side walls 103 of the optoelectronic semiconductor chip 11.

In general, first and second contact elements 127, 137 may have a square or rectangular cross-sectional shape. According to further embodiments, however, it is possible for them to have a different cross-sectional shape. For example, they may have a circular, oval, polygonal or other cross-sectional shape, as long as this shape is compatible with the feature of the corresponding contact element being adjacent to the lateral surface of the semiconductor chip 11.

FIG. 1C shows a top view of a second main surface 104 of the optoelectronic semiconductor chip 11 in accordance with further embodiments. In contrast to the embodiments shown in FIG. 1B, the second contact element 137 is adjacent to a total of three side walls 103 of the semiconductor chip. That is, in a Y direction, the second contact element 137 extends entirely between two adjacent side walls 103 of the semiconductor chip 11.

FIG. 2A shows a cross-sectional view through optoelectronic semiconductor chips 11 according to further embodiments. In contrast to the embodiments shown in FIG. 1a, the first contact element 127 likewise extends to a lateral surface 103 of the optoelectronic semiconductor chip. It becomes clear from the representation chosen in FIGS. 1A and 2A, in which adjacent chips are arranged in mirror image to one another, that second contact elements 137 of neighboring semiconductor chips may easily be produced using common methods by arranging each of the second contact elements 137, for example, on a lateral surface 103 of the optoelectronic semiconductor chip. As an example, a conductive structure 130 that is associated with two or more adjacent semiconductor chips may be divided.

FIG. 2B shows a schematic top view of a second main surface 104 of the optoelectronic semiconductor chip according to embodiments. FIG. 2B again illustrates dividing lines 106 along which the chips 11 may be singulated. According to the embodiments illustrated in FIG. 2B, both the first and the second contact element 127, 137 may each be adjacent to only one lateral surface 103 of the semiconductor chip. A part of the potting compound 140 may also be arranged between the first contact element 127 and the lateral surface 103, which is opposite in the Y direction, and between the second contact element 137 and the lateral surface 103, which is opposite in the Y direction.

According to the embodiments illustrated in FIG. 2C, the first contact element 127 may be adjacent to three side walls 103 of the optoelectronic semiconductor chip. The second contact element 137 may likewise be adjacent to three side walls 103 of the optoelectronic semiconductor chip 11. Both the first and the second contact element 127, 137 may in this case extend in a lateral direction, for example the Y direction, from one lateral chip surface 103 to the other lateral chip surface 103. They may thus be formed in the shape of strips. The potting compound 140 is arranged between the first and the second contact elements 127, 137 in each case.

FIG. 2D shows a top view of the second main surface 104 of the optoelectronic semiconductor chip 11 according to further embodiments. In this case, the first contact element 127 and/or the second contact element 137 are patterned in such a way that a lateral surface 117 or 118 of the contact element which is different from a lateral surface of the semiconductor chip extends along at least two different directions. Due to the special development of the lateral surfaces 117, 118 of the first and second contact elements 127, 137 and to the corresponding shape of the interposed potting compound 140, an anchoring structure 108 is created, by which the stability of the arrangement of the first and second contact elements 127, 137 and the potting compound 140 is increased. Furthermore, crack formation between the contact elements 127, 137 and the potting compound 140 may thereby be compensated for or suppressed.

The described arrangement of the first or second contact element allows for the chip size to be further reduced without incurring any issues regarding electrical contacting. For example, a minimum distance between the contact elements should be maintained for reliable insulation of the first and second contact elements 127, 137. Owing to the fact, that at least one of the first and second contact elements 127, 137 is adjacent to a lateral surface, it is possible to maintain this minimum distance even as miniaturization progresses, without the surface of the first or second contact element 127 or 137 inevitably falling below a critical value. Furthermore, if adjacent chips are arranged in mirror image to one another during the manufacturing process, adjacent chips may share conductive structures for forming contact elements. In this way, conductive structures 130 for forming contact elements of adjacent chips may be produced at a constant or not significantly reduced size, despite progressive miniaturization, and then divided. A further saving of surface area results from the fact that no potting compound 140 is arranged between the corresponding contact element and the lateral surface 103 of the semiconductor chip 11.

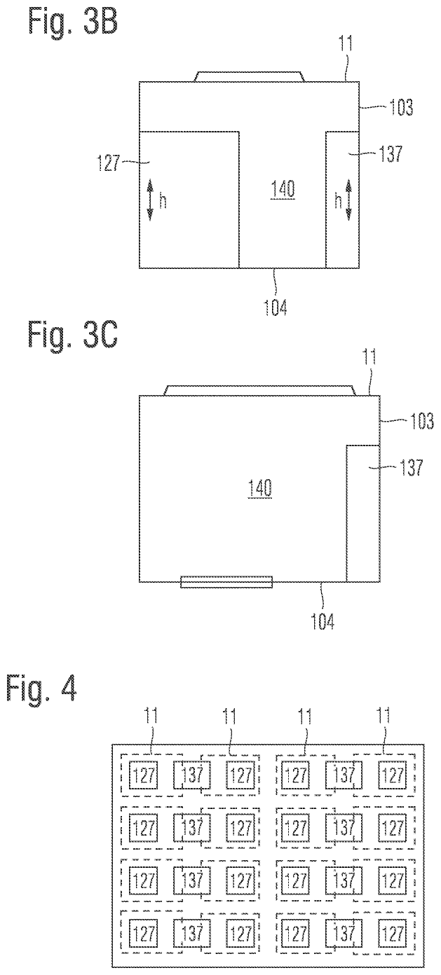

FIG. 3A shows a schematic cross-sectional view of an optoelectronic component comprising the optoelectronic semiconductor chip 11 as described above and a lead frame (“substrate”) or support 150. The optoelectronic semiconductor chip 11 is mounted on the lead frame 150. Contact elements 127, 137 are electrically connected to contact regions 152, 153 of the lead frame. According to embodiments, the first contact element 127 extends laterally to at least one lateral surface 103 of the optoelectronic semiconductor chip. According to further embodiments, the second contact element, too, extends laterally to at least one lateral surface 103 of the optoelectronic semiconductor chip. As the first and second contact elements 127, 137 are formed in a column-like or post-like shape, they extend in the vertical direction along the lateral surface 103 up to a height h. Accordingly, it is possible for a connecting material 109 or solder material for electrically connecting, for example, the first contact element 127 and the first contact region 152 of the lead frame 150 to extend along a vertical direction of optoelectronic semiconductor chip 11. In a corresponding manner, it is possible for the connection material 109 to extend on the second contact element 137 exposed on the lateral surface of the semiconductor chip 11 along a vertical direction of the optoelectronic semiconductor chip 11. In this way, the connecting surface may be enlarged. Furthermore, the mechanical stability of the connection and of the optoelectronic component 20 may be increased. According to further embodiments, however, it is also possible for the first or second contact element not to extend to the edge region 103. In this case, the contact element that does not extend to the edge region 103 may be connected along the horizontal contact surface.

FIG. 3B shows a schematic side view of a semiconductor chip 11 comprising a first and a second contact element 127, 137. A portion of the first contact element 127 is exposed on a vertical lateral surface 103 of the optoelectronic semiconductor chip 11. In a corresponding manner, a vertical portion of the second contact element 137 is exposed along the lateral surface 103 and is not covered. The exposed regions of the first and second contact elements 127, 137 may, for example, have a height h of 40 to 80 μm. For example, FIG. 3B may be a side view of the semiconductor chip 11 shown in FIG. 2C.

FIG. 3C shows a schematic side view through an optoelectronic semiconductor chip 11 according to further embodiments. Here, the lateral surface of only one contact element, in this case the second contact element 137, is exposed. The first contact element 127 is not adjacent to the lateral surface 103 of the semiconductor chip. Alternatively, of course, a lateral surface of the first contact element 127 may be exposed, while a lateral surface of the second contact element 137 is not adjacent to the lateral surface 103 of the optoelectronic semiconductor chip 11. For example, FIG. 3C may be a side view of the semiconductor chip 11 shown in FIG. 1C.

In the embodiments described here, the specific structure of the optoelectronically active layers, which are suitable for emitting or receiving electromagnetic radiation, is not critical and may be embodied in a manner different from that than shown in FIG. 1A or 1B. The semiconductor component is in each case designed as a flip-chip component.

FIG. 4 shows a top view of a second main surface of an arrangement of optoelectronic semiconductor chips 11, which may in each case be embodied as shown in FIG. 1A shown. That is, a plurality of optoelectronic semiconductor chips 11 are arranged in rows and columns, the second contact elements 137 of adjacent semiconductor chips 11 being arranged adjacent to one another. In a corresponding manner, the first contact elements 127 of adjacent semiconductor chips 11 are each arranged adjacent to one another. In this way, the second contact elements 137 of respectively adjacent chips may be produced by one process and separated from one another by the subsequent singulation process for singulating the semiconductor chips 11.

The concept described may also be applied to optoelectronic semiconductor components with pixelated chips, as will be described below.

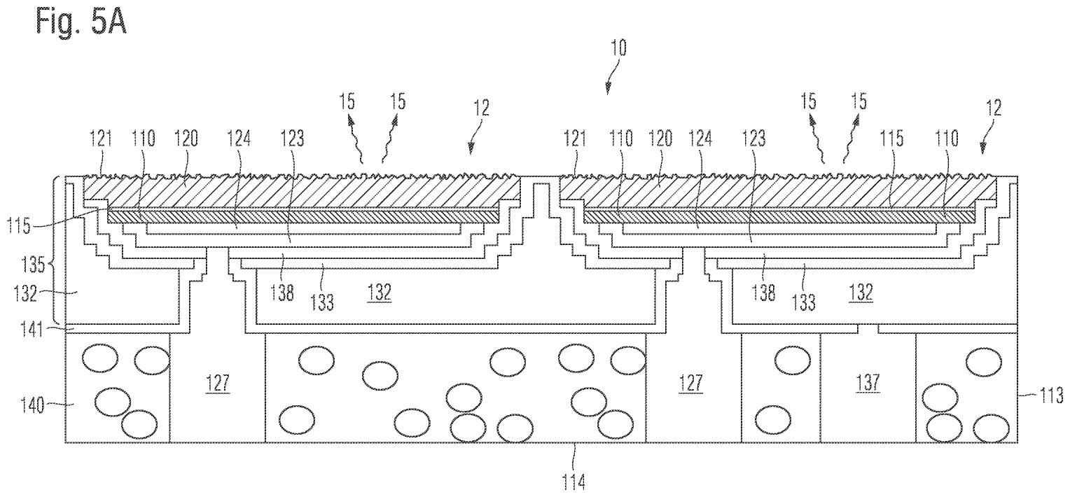

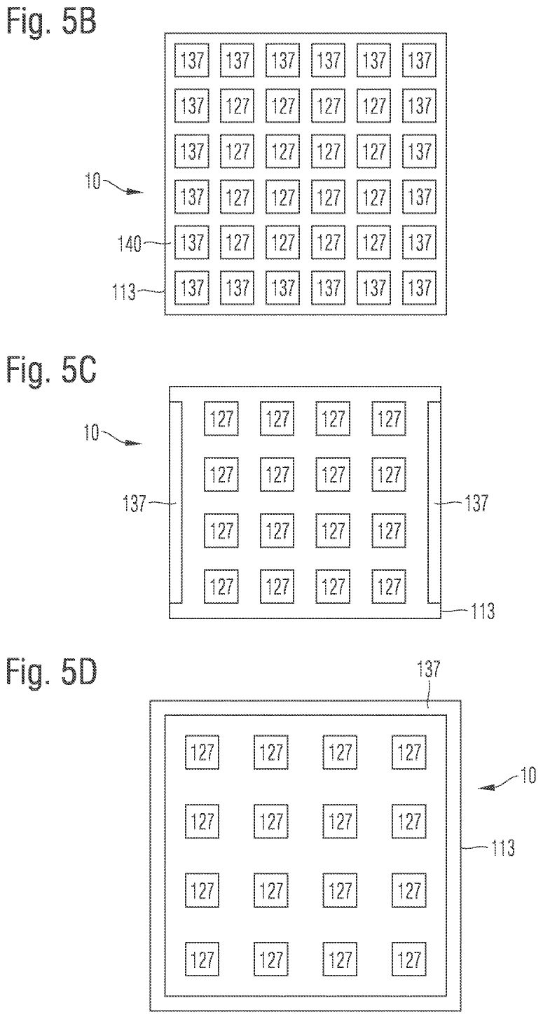

FIG. 5A shows a cross-sectional view through an optoelectronic semiconductor component 10 comprising a plurality of optoelectronic regions 12 (“pixels”). The optoelectronic regions 12 each comprise a first semiconductor layer 110 of a first conductivity type, for example p-type, and a second semiconductor layer 120 of a second conductivity type, for example n-type. The first semiconductor layer and the second semiconductor layer form a layer stack. Furthermore, the optoelectronic regions 12 each contain a first current spreading layer 123 and a first contact element 127. Electromagnetic radiation 15 emitted or received by the optoelectronic region is output or received via a first main surface 121 of the second semiconductor layer 120. The first current spreading layer 123 is arranged on a side of the first semiconductor layer 110 facing away from the second semiconductor layer 120 and is connected to the first semiconductor layer 110 in an electrically conductive manner. The first contact element 127 is connected to the first current spreading layer 123. The optoelectronic semiconductor component 10 further comprises a second current spreading layer 132 and a second contact element 137. The second current spreading layer 132 is arranged on the side of the first semiconductor layer 110 facing away from the second semiconductor layer 120 and is in each case connected to the second semiconductor layer 120 of the individual optoelectronic regions 12 in an electrically conductive manner. The second contact element 137 is connected to the second current spreading layer 132 in an electrically conductive manner.

As described, the optoelectronic semiconductor component comprises a plurality of first contact elements, a first contact element being associated with each optoelectronic region. The individual optoelectronic regions 12 are each separated from one another and may be controlled individually via the first contact element.

According to embodiments, the individual optoelectronic regions 12 may be configured in a manner similar to that of the optoelectronic semiconductor chips 11. In contrast to the construction shown, for example, in FIG. 1A, however, the second current spreading layer 132 is connected to the second semiconductor layers 120 of a plurality of optoelectronic regions 12, for example all of the optoelectronic regions 12. In this way, the optoelectronic regions 12 may each be controlled by controlling the associated first current spreading layers 123. Owing to the fact that a second current spreading layer 132 connects a plurality of second semiconductor layers 120 of different optoelectronic regions 12 to one another, a more compact configuration of the optoelectronic semiconductor component 10 may be achieved.

FIGS. 5B to 5D show schematic top views of the second main surface 114 of the optoelectronic semiconductor component 10. As illustrated in FIG. 5B, a plurality of first contact elements 127 is arranged in a central region of the optoelectronic semiconductor component 10. A plurality of second contact elements 137 surrounds the first contact elements 127 in an annular manner. That is, each of the outermost contact elements of the arrangement of contact elements is a second contact element 137, while each first contact element 127 comprises further contact elements adjacent to the lateral surface of the contact element 127.

As furthermore shown in FIG. 5B, the second contact elements 137 are not necessarily adjacent to a lateral surface 113 of the optoelectronic semiconductor component 10. A potting compound 140 may be arranged between the individual contact elements and in particular between the second contact elements 137 and the lateral surface 113 of the optoelectronic semiconductor component. According to further embodiments, however, the second contact elements 137 may also be adjacent to the lateral surface 113 of the optoelectronic semiconductor component.

FIG. 5C shows a schematic top view of the second main surface 114 of the optoelectronic semiconductor component 10. As may be seen, a multiplicity of second contact elements 137 are connected to one another and are formed in the shape of strips. According to embodiments, the second contact elements 137 may be adjacent to a lateral surface 113 of the optoelectronic semiconductor component 10. According to further embodiments, the second contact elements may be formed in a linear manner and may not be adjacent to the lateral surface 113 of the optoelectronic semiconductor component. In this case, potting compound may be arranged between the linearly formed second contact elements 137 and the lateral surface 113 of the optoelectronic semiconductor component. According to further embodiments, linearly formed second contact elements 137 may be arranged on all four lateral surfaces 113 of the optoelectronic semiconductor component 10.

FIG. 5D shows an arrangement in which the second contact elements 137 are formed in an annular and continuous manner. Furthermore, the contact element formed as a second contact element 137 in an annular manner is adjacent to all of the lateral surfaces 113 of the optoelectronic semiconductor component 10. The first contact elements 127 are arranged within the ring. With such an arrangement, encapsulation of the respective connecting material 109 between, for example, all first contact elements 127 of the semiconductor component 10 and the lead frame 150 may be achieved after the semiconductor component 10 has been applied to a support or lead frame 150.

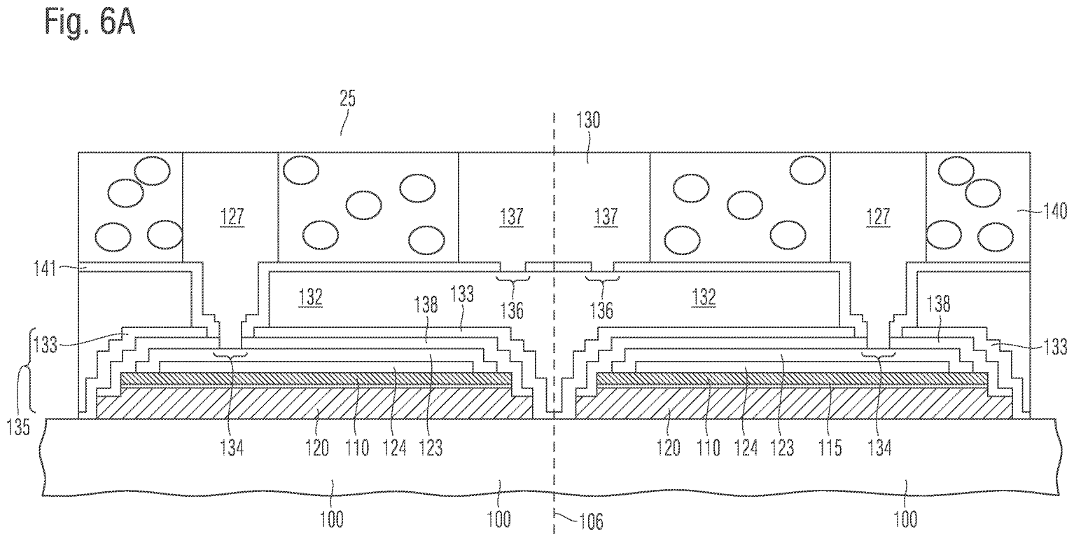

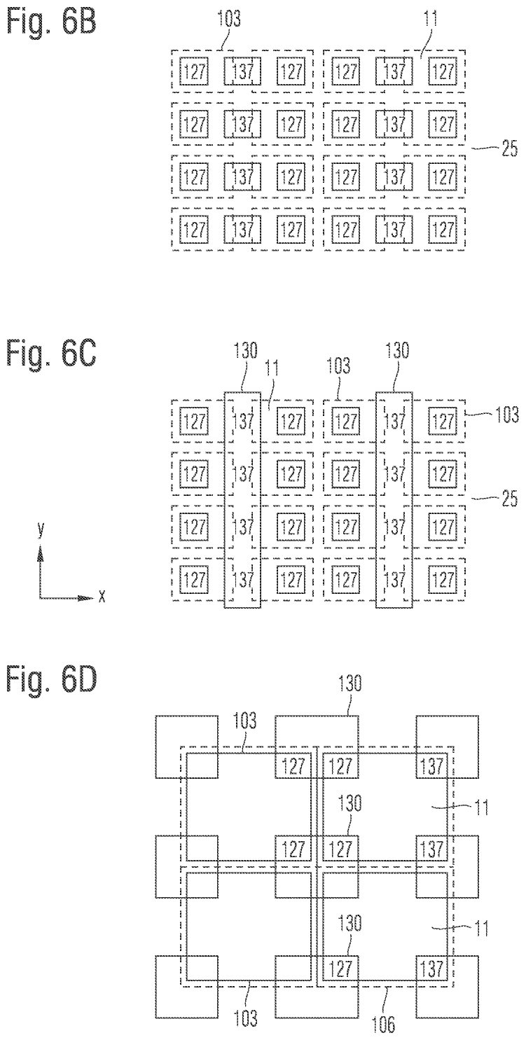

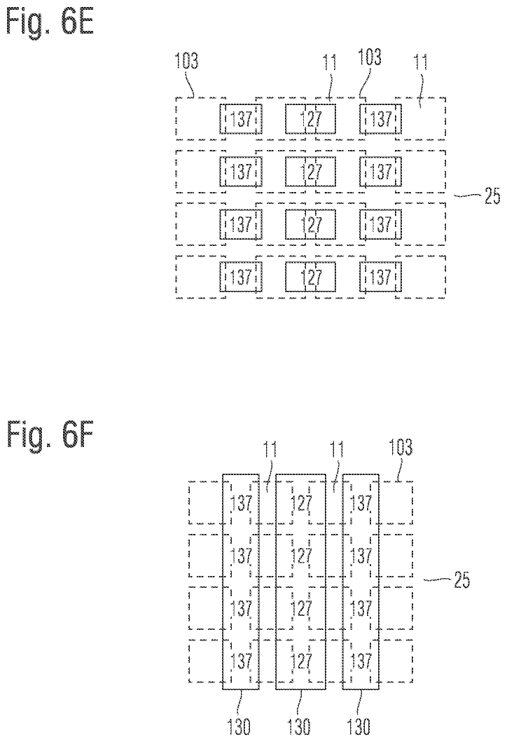

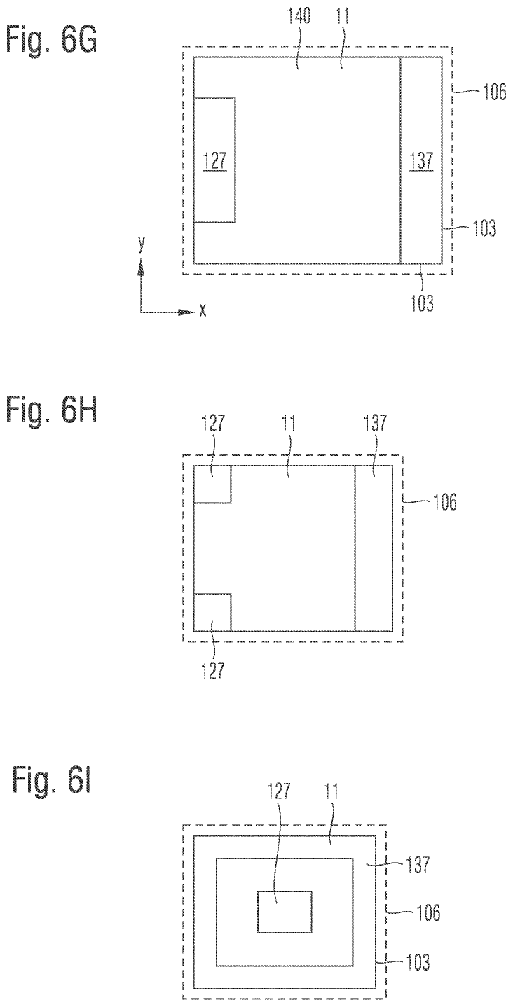

FIG. 6A shows a workpiece 25 during the production of the optoelectronic semiconductor chips 11 described. For the purpose of producing the optoelectronic semiconductor chip 11, the second semiconductor layer 120, the active zone 115 and the first semiconductor layer 110 are grown epitaxially over a suitable growth substrate 100, for example a sapphire substrate 100. The grown layers are patterned into mesas. For example, the mirror layer 124 and the second current spreading layer 123 are formed above the grown and patterned layer stack and patterned further. An insulation layer 138 is then applied over the resulting structure. The insulation layer 138 may comprise, for example, SiO₂, SiN, Al₂O₃, combinations of these materials, and further dielectrics. The stoichiometric ratios of the dielectrics may differ from those given.

Furthermore, the contact layer 133 and the second current spreading layer 132 are then applied, for example. The second current spreading layer 132 may be applied, for example, by sputtering, galvanic processes, electroless plating (plating without external current) or vapor deposition. The second current spreading layer 132 and the contact layer 133 are each laterally guided along the layer stack made up of the first and second semiconductor layers 110, 120, so that the edge region of the support element 135 is formed. In doing so, the first semiconductor layer 110 is insulated from the second current spreading layer 132 or the contact layer 133 by the insulating material 138. The second semiconductor layer 120 is connected to the second current spreading layer 132 via the contact material 133. For example, the second current spreading layer 132 and thus the support element 135 may contain nickel. The second current spreading layer 132 may, for example, have a layer thickness of 3 to 20 μm, for example 10 μm.

Openings 134 are then formed in the second current spreading layer 132 and the contact layer 133 and in the insulation layer 138. These openings will later serve to establish the contact to the first current spreading layer 123. A passivation layer 141, for example made of SiO₂, is formed over the second current spreading layer 132 and adjacent to the side walls of the openings 134. Furthermore, openings 136 are formed in the passivation layer 141, through which the second contact element 137 may be connected to the second current spreading layer 132. According to embodiments, the first and the second contact element 127, 137 are then formed, for example by galvanic processes. As an example, the first and second contact elements 127, 137 or the conductive structures for producing the first or second contact element may include or be composed of nickel or copper. As an example, a suitable photoresist material may be applied and then patterned. The first and second contact elements 127, 137 are formed on the exposed regions by the subsequent galvanic process. The first contact element 127 is formed, for example, in contact with a conductive structure or the first current spreading layer 123. The second contact element 137 is formed in contact with the second current spreading layer 132, for example.

In the workpiece, the second contact elements 137 of adjacent semiconductor chips are arranged directly next to one another, as shown in FIG. 6A. To form the second contact elements 137 of adjacent semiconductor chips, a conductive structure 130 is formed and severed during the subsequent singling process, so that two second contact elements 137 of adjacent semiconductor chips are formed. Depending on the configuration, a conductive structure may be associated with a plurality of adjacent semiconductor chips and thus form a plurality of contact elements, as is also explained in FIGS. 6B to 6F below. Furthermore, the first contact elements of adjacent semiconductor chips may be arranged next to one another in a corresponding manner. Furthermore, a conductive structure 130 may be formed which, upon singulation into individual chips, is divided into two or more first contact elements 127 of adjacent semiconductor chips.

A potting compound is then poured in, by means of which the first and second contact elements 127, 137 are isolated from one another. The potting compound may, for example, contain epoxy, acrylate, bismaleimides, triazines, silicone, polysiloxanes, polysilazanes or mixtures of these materials. It may contain fillers, such as fibers (e.g., glass fibers, carbon fibers), particles (e.g., SiO₂, CaF, TiO₂, ZrO₂, BN, SiC, Al₂O₃, ALN, graphene or diamond), dyes, absorbers (e.g., UV absorbers), reflectors (e.g., aluminum), stabilizers, or process-supporting materials (e.g., mold release agents).

Furthermore, the potting compound may be ground back in order to expose a surface of each of the first and second contact elements 127, 137. The growth substrate 100 is then removed, for example, by a laser lift-off method. The individual chips are then separated from one another by sawing, for example, or by other separation methods, for example laser dicing or plasma etching.

FIG. 6B shows a plan view of a second main surface of the workpiece 25 before the singulation process is carried out. FIG. 6B illustrates the positions of each of the first and second contact elements 127, 137 as well as the semiconductor chip sides 103 within the workpiece 25 prior to singulation into individual semiconductor chips 11. In the arrangement shown in FIG. 6B, the chips are arranged in such a way that the second contact elements 137 of adjacent chips are adjacent to one another. Furthermore, the first contact elements 127 of adjacent chips are each adjacent to one another. In particular, the conductive structures for forming the second contact elements 137 are each formed in such a way that each conductive structure is split up during singulation of the workpiece 25 and is associated with two different semiconductor chips.

According to the embodiments shown in FIG. 6C, the conductive structures for forming the second contact elements 137 may each be formed in the shape of strips. As an example, the photoresist mask for forming the second contact element is patterned in such a way that a strip-shaped region is exposed which connects a plurality of adjacent semiconductor chips 11 in the Y direction and two adjacent semiconductor chips at a time in the X direction.

FIG. 6D shows a top view of a workpiece 25 according to further embodiments, in which one conductive structure 130 for forming a first or second contact element 127, 137 is in each case associated with four adjacent chips 11 and forms four contact elements of the associated chips 11 during subsequent singulation. In particular, the conductive structure 130 may be formed in such a way that it is arranged in four adjoining corner regions of the chip 11.

FIG. 6E shows a top view of a workpiece 25 according to further embodiments. According to these embodiments, a conductive structure for forming both first contact elements 127 and second contact elements 137 is associated with two adjacent chips in the X direction. As illustrated, for example, in FIGS. 6B, 6C and 6E, the saw track width, i.e. the width of the sawing frame (kerf) 107 on adjacent chips within the workpiece 25 may vary. As a result, with a process-related minimum size of the conductive structures 130 which form the contact elements 127 and 137 of the semiconductor chips 11 after the workpiece 25 has been singulated, a smaller minimum size of the semiconductor components 10 or semiconductor chips 11 may be achieved.

FIG. 6F shows a top view of a second main surface of a workpiece according to further embodiments. In these embodiments, a conductive structure for forming both first and second contact elements 127, 137 is formed in a strip-like manner, so that two adjacent chips in the X direction and a plurality of adjacent chips in the Y direction share the conductive structure. As a result, a plurality of first or second contact elements 127, 137 may be singulating after separating the conductive structure.

FIGS. 6G to 6I illustrate top views of a second main surface 104 of optoelectronic semiconductor chips 11, and they show the specific arrangement of the first and second contact elements 127, 137. It must be taken into account here that the first and second contact elements 127, 137 may each be interchanged with one another. As shown in FIG. 6G, the second contact element 137 extends in the shape of a strip along the Y direction. Correspondingly, the second contact element 137 is adjacent to three lateral surfaces 103 of the optoelectronic semiconductor chip 11. In contrast, the first contact element 127 is adjacent to only one lateral surface 103 of the optoelectronic semiconductor chip 11. A respective portion of the potting compound 140 is arranged in the Y direction between the contact element 127 and the lateral surface 103.

As illustrated in FIG. 6H, the first contact elements 127 are each arranged at the corners of the optoelectronic semiconductor chip 11. The second contact element 137 is formed in the shape of a strip as shown in FIG. 6G.

As shown in FIG. 6I, the second contact element 137 is formed in an annular shape. The first contact element 127 is located in a central region of the chip. Correspondingly, the second contact element 137 is adjacent to all of the lateral surfaces 103 of the optoelectronic semiconductor chip 11.

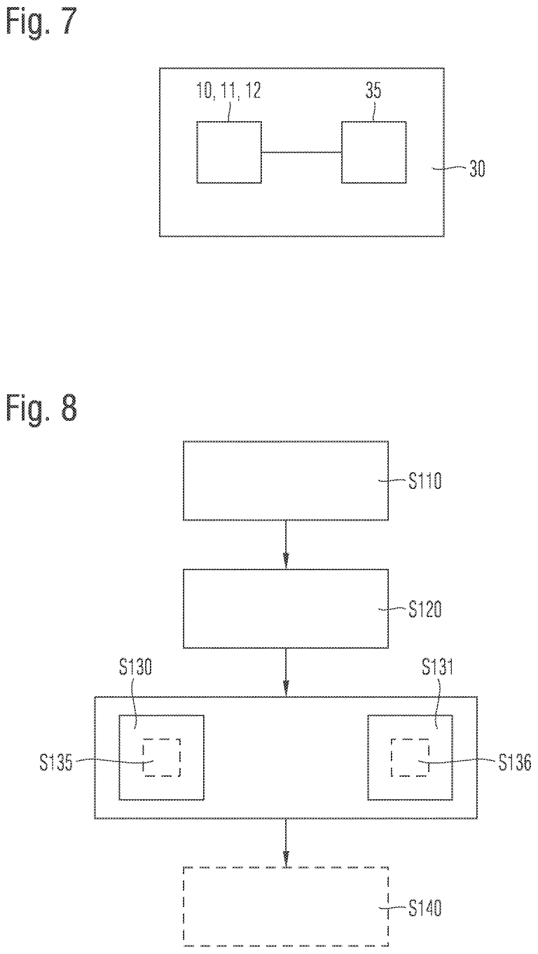

FIG. 7 shows an optoelectronic device 30 according to embodiments. The optoelectronic device 30 may, for example, include the optoelectronic semiconductor chip 11 or the optoelectronic semiconductor component 10 or the optoelectronic component 20 as described above.

Examples of optoelectronic devices 30 comprising the optoelectronic semiconductor chip 11 or the optoelectronic component 20 include, for example, applications with small chips, for example applications in which lighting that is not very bright is useful, for example display devices in motor vehicles and display devices for other fields of application.

Examples of optoelectronic devices 30 comprising the optoelectronic semiconductor component 10 include, for example, devices with a plurality of individual segments which may be controlled separately. FIG. 7 shows a driver circuit 35, by means of which the individual segments or the first contact elements of the optoelectronic semiconductor component 10 may each be controlled. Specific examples of the optoelectronic device comprising the optoelectronic semiconductor component 10 include lighting systems with selectively controllable lighting elements, vehicle lights, for example with an integrated driver circuit 35, video walls, for example comprising semiconductor components 10 that emit light in different colors (RGB) and flash light.

FIG. 8 outlines a method according to embodiments.

A method for producing an optoelectronic semiconductor chip comprises forming (S110) a layer stack comprising a first semiconductor layer of a first conductivity type and a second semiconductor layer of a second conductivity type, forming (S120) a first and a second current spreading layer, and forming (S130, S131) first and second contact elements.

The first current spreading layer is formed on a side of the first semiconductor layer facing away from the second semiconductor layer and is connected to the first semiconductor layer in an electrically conductive manner. The second current spreading layer is formed on the side of the first semiconductor layer facing away from the second semiconductor layer and is connected to the second semiconductor layer in an electrically conductive manner. The first contact element is connected to the first current spreading layer. The second contact element is connected to the second current spreading layer. The first or second contact element extends laterally to at least one lateral surface of the optoelectronic semiconductor chip.

As an example, the method includes processing a wafer including a plurality of semiconductor chips, wherein the first or second contact elements of adjacent semiconductor chips are each arranged adjacent to one another. In this case, forming (S130) the first contact elements comprises forming (S135) a conductive structure which is associated with several adjacent semiconductor chips. The method may furthermore comprise singulating (S140) the wafer into semiconductor chips, the conductive structure being divided among the associated semiconductor chips. Furthermore, forming (S131) the second contact elements may comprise forming (S136) a conductive structure which is associated with a plurality of adjacent semiconductor chips.

Although specific embodiments have been illustrated and described herein, those skilled in the art will recognize that the specific embodiments shown and described may be replaced by a multiplicity of alternative and/or equivalent configurations without departing from the scope of the claims. The application is intended to cover any adaptations or variations of the specific embodiments discussed herein. Therefore, the invention is to be limited by the claims and their equivalents only.

### LIST OF REFERENCES

10 optoelectronic semiconductor component
11 optoelectronic semiconductor chip
12 optoelectronic region (“pixel”)
15 emitted radiation
20 optoelectronic component
25 workpiece
30 optoelectronic device
35 driver circuit
100 growth substrate
103 lateral surface of the semiconductor chip
104 second main surface of the semiconductor chip
106 separating line
107 sawing frame (kerf)
108 anchoring structure
109 connecting material (solder)
110 first semiconductor layer
113 lateral surface of the optoelectronic semiconductor component
114 second main surface of the optoelectronic semiconductor component
115 active zone
117 lateral surface of the first contact element
118 lateral surface of the second contact element
120 second semiconductor layer
121 first main surface of the second semiconductor layer
123 first current spreading layer
124 mirror layer
127 first contact element
130 conductive structure
132 second current spreading layer
133 contact layer
134 opening
135 support element
136 opening
137 second contact element
138 insulating layer
140 potting compound
141 insulating material
150 lead frame (“substrate”)
152 first contact region
153 second contact region

1. (canceled)

2. (canceled)

3. The optoelectronic semiconductor component according to claim 28, wherein the potting compound and parts of the first or second contact element form lateral surfaces of the optoelectronic semiconductor chip.

4. The optoelectronic semiconductor component according to claim 10, wherein the first or second contact element extends laterally to at least two lateral surfaces of the optoelectronic semiconductor chip.

5. The optoelectronic semiconductor component according to claim 10, wherein the second current spreading layer extends along a sidewall of the layer stack comprising the first and the second semiconductor layers, so that an edge region of the support element is formed; and wherein the first current spreading layer is connected with the first semiconductor layer via an opening in the second current spreading layer.

6. The optoelectronic semiconductor chip component according to claim 10, wherein the first current spreading layer is arranged adjacent to the first semiconductor layer and parts of the second current spreading layer are arranged on a side of the first current spreading layer facing away from the first semiconductor layer.

7. The optoelectronic semiconductor component according to claim 10, wherein a lateral surface of the first or second contact element different from a lateral surface of the semiconductor chip extends along at least two directions to form an anchoring structure.

8. The optoelectronic component according to claim 10, further comprising a lead frame wherein the optoelectronic semiconductor chip is mounted on the lead frame and the contact elements of the optoelectronic semiconductor chip are electrically connected to contact regions of the lead frame.

9. The optoelectronic component according to claim 8, wherein a connecting material for electrically connecting the contact elements to the contact regions of the lead frame extends along an exposed contact element in a vertical direction of the optoelectronic semiconductor chip.

10. An optoelectronic component comprising an optoelectronic semiconductor chip wherein the optoelectronic semiconductor chip comprises:
a first semiconductor layer of a first conductivity type;
a second semiconductor layer of a second conductivity type;
first and second current spreading layers; and
first and second contact elements;
wherein:
the first and second semiconductor layers form a layer stack;
the first current spreading layer is arranged on a side of the first semiconductor layer facing away from the second semiconductor layer and is connected to the first semiconductor layer in an electrically conductive manner;
the second current spreading layer is arranged on a side of the first semiconductor layer facing away from the second semiconductor layer and is electrically connected to the second semiconductor layer; wherein the second current spreading layer forms a support element of the optoelectronic semiconductor chip;
the first contact element is connected to the first current spreading layer;
the second contact element is connected to the second current spreading layer;
the first contact element extends laterally to at least one lateral surface of the optoelectronic semiconductor chip and is directly adjacent to a second main surface of the optoelectronic semiconductor chip.

11. An optoelectronic component comprising an optoelectronic semiconductor chip; wherein the optoelectronic semiconductor chip comprises:
a first semiconductor layer of a first conductivity type;
a second semiconductor layer of a second conductivity type;
first and second current spreading layers; and
first and a second contact elements;
wherein:
the first and second semiconductor layers form a layer stack;
the first current spreading layer is arranged on a side of the first semiconductor layer facing away from the second semiconductor layer and is connected to the first semiconductor layer in an electrically conductive manner;
the second current spreading layer is arranged on a side of the first semiconductor layer facing away from the second semiconductor layer and is electrically connected to the second semiconductor layer; wherein the second current spreading layer forms a support element of the optoelectronic semiconductor chip;
the first contact element is connected to the first current spreading layer;
the second contact element is connected to the second current spreading layer; and
the second contact element extends laterally to at least one lateral surface of the optoelectronic semiconductor chip and is directly adjacent to a second main surface of the semiconductor chip.

12. The optoelectronic semiconductor component according to claim 29, wherein the potting compound and portions of the first or second contact element extends laterally to at least two lateral surfaces of the optoelectronic semiconductor chip.

13. The optoelectronic semiconductor component according to claim 11, wherein the second current spreading layer extends along a sidewall of the layer stack comprising the first and the second semiconductor layers, so that an edge region of the support element is formed; and wherein the first current spreading layer is connected with the first semiconductor layer via an opening in the second current spreading layer.

14. The optoelectronic semiconductor component according to claim 11, wherein a lateral surface of the first or second contact element different from a lateral surface of the semiconductor chip extends along at least two directions to form an anchoring structure.

15. An optoelectronic component according to claim 11 further comprising a lead frame, wherein the optoelectronic semiconductor chip is mounted on the lead frame and the contact elements of the optoelectronic semiconductor chip are electrically connected to contact regions of the lead frame.

16. The optoelectronic component according to claim 15, wherein a connecting material for electrically connecting the contact elements to the contact regions of the lead frame extends along an exposed contact element in a vertical direction of the optoelectronic semiconductor chip.

17-22. (canceled)

23. An optoelectronic semiconductor component, comprising an array of optoelectronic regions each comprising:
a first semiconductor layer of a first conductivity type;
a second semiconductor layer of a second conductivity type;
a first current spreading layer; and
a first contact element;
wherein:
the first and second semiconductor layers form a layer stack;
the first current spreading layer is arranged on a side of the first semiconductor layer facing away from the second semiconductor layer and is connected to the first semiconductor layer in an electrically conductive manner;
the first contact element is connected to the first current spreading layer;
wherein the optoelectronic semiconductor component further comprises a second current spreading layer and a second contact element;
wherein the second current spreading layer is arranged on a side of the first semiconductor layer facing away from the second semiconductor layer and is respectively connected to the second semiconductor layer of the optoelectronic regions in an electrically conductive manner; and
the second contact element is connected to the second current spreading layer.

24. The optoelectronic semiconductor component according to claim 23, comprising a plurality of second contact elements.

25. The optoelectronic semiconductor component according to claim 24, wherein the second contact elements are arranged in an edge region of the optoelectronic semiconductor component.

26-27. (canceled)

28. The optoelectronic semiconductor component according to claim 10, further comprising a potting compound arranged between the first and the second contact elements.

29. The optoelectronic semiconductor component according to claim 11, further comprising a potting compound arranged between the first and the second contact elements.

30. The optoelectronic component according to claim 11, wherein the first or second contact element extends laterally to at least two lateral surfaces of the optoelectronic semiconductor chip.
